(19) United States
(12) Patent Application Publication
(10) Pub. No.: US 2010/0216295 A1
(43) Pub. Date: Aug. 26, 2010

(54) SEMICONDUCTOR ON INSULATOR MADE USING IMPROVED DEFECT HEALING PROCESS

(76) Inventor: Alex Usenko, Painted Post, NY (US)

Correspondence Address: CORNING INCORPORATED, SP-TI-3-1, CORNING, NY, 14831, US

(21) Appl. No.: 12/391,340

(22) Filed: Feb. 24, 2009

(51) Int. Cl. H01L 21/326; H01L 21/20

(52) U.S. Cl. 438/470; 438/481; 438/487; 257/E21.6; 257/E21.7

(57) ABSTRACT

Methods and apparatus for producing a semiconductor on glass (SOG) structure include: subjecting an implantation surface of a donor semiconductor wafer to an ion implantation process to create an exfoliation layer of the donor semiconductor wafer; bonding the implantation surface of the exfoliation layer to a glass substrate using electrolysis; separating the exfoliation layer from the donor semiconductor wafer, thereby exposing at least one cleaved surface; subjecting the at least one cleaved surface to an amorphization ion implantation process at a dose sufficient to amorphize at least some depth of the semiconductor material below the at least one cleaved surface; and re-growing the amorphized portion of the semiconductor material into a substantially single crystalline semiconductor layer using solid phase epitaxial re-growth

### BACKGROUND

The present invention relates to the manufacture of a semiconductor-on-insulator (SOI) structure using an improved defect healing process.

To date, the semiconductor material most commonly used in semiconductor-on-insulator structures has been silicon. Such structures have been referred to in the literature as silicon-on-insulator structures and the abbreviation “SOI” has been applied to such structures. SOI technology is becoming increasingly important for high performance thin film transistors, solar cells, and displays, such as, active matrix displays. SOI structures may include a thin layer of substantially single crystal silicon on an insulating material.

For ease of presentation, the following discussion will at times be in terms of SOI structures. The references to this particular type of SOI structure are made to facilitate the explanation of the invention and are not intended to, and should not be interpreted as, limiting the invention's scope in any way. The SOI abbreviation is used herein to refer to semiconductor-on-insulator structures in general, including, but not limited to, semiconductor-on-glass (SOG) structures, silicon-on-insulator (SOI) structures, and silicon-on-glass (SiOG) structures, which also encompasses silicon-on-glass-ceramic structures.

Various ways of obtaining SOI structures include epitaxial growth of silicon (Si) on lattice matched substrates. An alternative process includes the bonding of a single crystal silicon wafer to another silicon wafer on which an oxide layer of SiO₂ has been grown, followed by polishing or etching of the top wafer down to, for example, a 0.05 to 0.3 micron layer of single crystal silicon. Further methods include ion-implantation methods in which either hydrogen or oxygen ions are implanted either to form a buried oxide layer in the silicon wafer topped by Si in the case of oxygen ion implantation or to separate (exfoliate) a thin Si layer to bond to another Si wafer with an oxide layer as in the case of hydrogen ion implantation.

The former two methods have not resulted in satisfactory structures in terms of cost and/or bond strength and durability. The latter method involving hydrogen ion implantation has received some attention and has been considered advantageous over the former methods because the implantation energies required are less than 50% of that of oxygen ion implants and the dosage required is two orders of magnitude lower.

U.S. Pat. No. 5,374,564 discloses a process to obtain a single crystal silicon film on a substrate using a thermal process. A silicon wafer having a planar face is subject to the following steps: (i) implantation by bombardment of a face of the silicon wafer by means of ions creating a layer of gaseous micro-bubbles defining a lower region of the silicon wafer and an upper region constituting a thin silicon film; (ii) contacting the planar face of the silicon wafer with a rigid material layer (such as an insulating oxide material); and (iii) a third stage of heat treating the assembly of the silicon wafer and the insulating material at a temperature above that at which the ion bombardment was carried out. The third stage employs temperatures sufficient to bond the thin silicon film and the insulating material together, to create a pressure effect in the micro-bubbles, and to cause a separation between the thin silicon film and the remaining mass of the silicon wafer. (Due to the high temperature steps, this process does not work with lower cost glass substrates.)

U.S. Pat. No. 7,176,528 discloses a process that produces an SiOG structure. The steps include: (i) exposing a silicon wafer surface to hydrogen ion implantation to create a bonding surface; (ii) bringing the bonding surface of the wafer into contact with a glass substrate; (iii) applying pressure, temperature and voltage to the wafer and the glass substrate to facilitate bonding therebetween; (iv) cooling the structure to a common temperature; and (v) separating the glass substrate and a thin layer of silicon from the silicon wafer.

The thin layer of semiconductor material (e.g., silicon) can be amorphous, polycrystalline, or of the single crystalline type. The amorphous and polycrystalline types of devices are less expensive than their single crystal counterparts, but they also exhibit lower electrical performance characteristics. The manufacturing processes for making SOI structures with amorphous or polycrystalline layers are mature, and the performance of final products employing them is limited by the properties of the semiconductor material. In contrast to the amorphous and polycrystalline semiconductor materials, which are low quality semiconductors, single crystalline semiconductor material (such as silicon) is considered of relatively higher quality. Thus, the use of higher quality semiconductor materials will enable the manufacture of better final devices.

Assuming that single crystalline semiconductor material (e.g., silicon) is used to form an SOI using the process of U.S. Pat. No. 7,176,528, the resulting SOI structure just after exfoliation sometimes exhibits excessive implantation damage of the silicon layer (e.g., due to the formation of an imperfect silicon layer) and residual implantation species (such as hydrogen). During implantation, the ion species (e.g., hydrogen ions) are accelerated into the silicon crystal lattice. While moving through the crystal lattice, the ions displace silicon atoms from their regular locations in the lattice. The displaced silicon atoms are thus disruptions in a properly ordered lattice, i.e., they are defects in an overall single crystalline media. Implanted ions eventually lose their kinetic energy and come to rest in the lattice. These ions are also defects in the crystal lattice, as they are not silicon atoms and they are not located in proper lattice locations. Therefore, after ion implantation, the donor silicon substrate will have hydrogen and displaced silicon atoms within and around a range of depths.

Further steps in the process of fabricating the SOI, such as bonding, exfoliation, annealing and/or polishing may result in partial or total removal of implantation-induced crystal damage. Bonding and exfoliation steps are usually performed at elevated temperatures, which drive hydrogen ions out of the lattice due to diffusion. To completely heal the implant-induced damaged by heating (e.g., annealing), the crystal has to be heated to a temperature approaching the melting temperature of the crystal semiconductor material. For silicon, the melting temperature is 1412° C., and heating to about 1100° C. is required to almost completely heal the post-implantation crystal damage. During the process of fabricating a silicon-on-glass device, annealing to temperatures above about 600° C. is prohibited because the glass warps or even melts at such high temperatures.

There are, however, several methods known in the art to efficiently heal damaged silicon layers on glass substrates. These methods include: (1) physical removal of the damaged part of the silicon layer, for example, by polishing or etching techniques; and (2) melting and re-crystallization of the transferred film using pulsed heating, for example, excimer laser annealing.

Physical removal of damaged silicon is described in U.S. Pat. No. 3,841,031. The polishing process involves holding and rotating a thin flat wafer of semiconductor material against a polishing surface under controlled pressure and temperature. When polishing a relatively thin transferred semiconductor film on a relatively thick substrate, however, the polishing action degrades the thickness uniformity of the transferred film. Typical surface non-uniformities (standard deviation/mean removal thickness) are in the 3-5% range for semiconductor films. As more of the silicon thickness is removed, the variation in the film thickness correspondingly worsens.

The above shortcoming of the polishing process is especially a problem for some silicon on glass applications because, in some cases, as much as about 300-400 nm of material needs to be removed to obtain a desired silicon film thickness. For example, in thin film transistor (TFT) fabrication processes, a silicon film thickness in the 100 nm range or less may be desired. Additionally, a low surface roughness may also be desirable for a TFT structure.

Another problem with the polishing process is that it exhibits particularly poor results when rectangular SOI structures (e.g., those having sharp corners) are polished. Indeed, the aforementioned surface non-uniformities are amplified at the corners of the SOI structure compared with those at the center thereof. Still further, when large SOI structures are contemplated (e.g., for photovoltaic applications), the resulting rectangular SOI structures are too large for typical polishing equipment (which are usually designed for the 300 mm standard wafer size). Cost is also an important consideration for commercial applications of SOI structures. The polishing process, however, is costly both in terms of time and money. The cost problem may be significantly exacerbated if non-conventional polishing machines are required to accommodate large SOI structure sizes.

Another process for removing damaged material from a transferred silicon film is described in U.S. Pat. No. 7,312,154. This method involves polishing away the top part of the transferred semiconductor layer (which is bonded to glass) while simultaneously measuring the thickness of the semiconductor from the substrate side of the semiconductor layer. The thickness measurement is used to modify the polishing characteristics of the process. This method results in less severe thickness uniformity degradation of the resulting semiconductor layer because the method replicates the thickness uniformity of the relatively thick substrate on the semiconductor layer it supports. Thus, the polished semiconductor layer conforms to the waviness of the underlying substrate, but maintains its thickness uniformity across the entire substrate. If the size of the waves on the surface of the glass substrate is smaller than the size of the polishing head, however, the conformity of the desired shape is not achieved, and the thickness uniformity degrades.

Melting and re-crystallization of the exfoliated semiconductor layer using excimer laser annealing is described in international publication WO/2007/142911. The excimer laser beam melts a top portion of the semiconductor layer while maintaining the glass substrate at a cooler temperature. This method results in poorer electrical characteristics within the annealed semiconductor material because the melted part of the single crystalline material solidifies too fast. In a regular Czochralski method of silicon growth, the rate of growth is around 1 millimeter per minute. In contrast, the re-growth rate of silicon melted and re-crystallized via an excimer laser is about 10E14 times faster. The relatively slow growth rate of the Czochralski method allows a nearly ideal crystal lattice to grow. At faster growth rates, there is not enough time for individual silicon atoms to diffuse to proper positions. Many silicon atoms are thus frozen at irregular locations, which means that they are structural defects in the newly formed lattice.

For polysilicon annealing, the excimer laser technique is effective, as the polysilicon can be approximated as a crystal with a very high level of structural defects. In an SOI obtained by exfoliation of a single crystal semiconductor layer, however, the initial number of defects of the semiconductor material is not as high as in polysilicon. While the excimer laser annealing technique may heal some or all of the initial defects in the semiconductor material, it introduces new defects in about the same concentration as before the annealing, or even higher. Thus, the excimer laser annealing technique results in only a marginal improvement in the electrical properties of the exfoliated semiconductor layer.

An additional problem with laser annealing is that the melted semiconductor material, such as silicon, is significantly denser than crystalline silicon (2.33 and 2.57 g/cm3 respectively). When the melted silicon solidifies after the excimer laser scan, the difference between the respective densities results in a characteristic, periodic fluctuation in the thickness of the re-melted silicon. Thus, the excimer laser annealed films are inherently non-smooth, which is a disadvantage.

For the reasons discussed above, none of the aforementioned techniques and processes for removing or otherwise correcting for damage to the semiconductor lattice structure has been satisfactory in the context of manufacturing SOG structures. Thus, there is a need in the art for a new process for manufacturing SOI structures, such as SOG structures, in order to reduce and/or eliminate the damage done to the semiconductor layer of the SOI structure during ion implantation.

### SUMMARY

A technique for healing defects in epitaxially grown semiconductor materials is described in S. S. Lau, S. Matteson, J. W. Mayer, P. Revesz, J. Gyulai, J. Roth, T. W. Sigmon, and T. Cass, “Improvement of crystalline quality of epitaxial Si layers by ion-implantation techniques”, Applied Physics Letters, Vol. 34, 1979, pp. 76-78. This technique has been called solid phase epitaxy (SPE). Using this technique, a part of the semiconductor layer is first amorphized by an ion implantation process, whereby ions of a species matching the material of the semiconductor layer (e.g., silicon) are implanted. Only part of the semiconductor layer is amorphized by such implantation, and the other part remains single crystalline. The single crystalline part serves as a seed to re-grow the amorphized part back into crystalline material. Next, the implanted structure is annealed at a temperature between 550° C. to 600° C. The amorphized layer re-crystallizes, and the entire epitaxial film again becomes single crystalline. This method has been used to improve the quality of a lower part of an epitaxially grown silicon film on sapphire. There have been improvements to this basic technique as described, for example, in U.S. Pat. No. 4,509,990, and U.S. Pat. No. 7,141,116. A summary of the state of the art in solid phase epitaxy may be found in Monography Epitaxy: Physical Foundation and Technical Implementation, by Marian A. Herman, Wolfgang Richter, Helmut Sitter, Springer, 2004, pp. 45-62. Prior applications of the SPE technique relate to healing defects of epitaxially grown semiconductor materials and post-implantation defects from implanted dopants.

It has been discovered that the SPE technique may be adapted for use in healing defects in single crystalline semiconductor layers (e.g., silicon layers) formed using the exfoliation transfer technique in SOI fabrication.

There are several characteristics of the exfoliated silicon layer of an SOI formed as discussed above. An uppermost portion of an exfoliated silicon layer as transferred to the substrate (e.g., glass) is not amorphous, as hydrogen ions used to create a weakened layer in the semiconductor donor wafer are not heavy enough as to amorphize the semiconductor material. The implantation dose used in the formation of the weakened layer is very high, much higher than doses used in doping techniques. Thus, the uppermost portion of the as-transferred exfoliated semiconductor layer may be described as a mix of semiconductor (e.g., silicon) and hydrogen. Also, the as-transferred exfoliated semiconductor layer has several types of defects that are unique to situations where heavy dose implantation of hydrogen into silicon has been carried out. For example, the as-transferred exfoliated layer contains hydrogen filled bubbles, hydrogen platelets, and hydrogenated vacancy clusters.

The above cited monograph describes that impurities in pre-amorphized silicon drastically affect the solid phase epitaxy phenomena. Some impurities strongly impede the solid phase epitaxy rate, while others do not affect the rate, and others strongly enhance the rate. Thus, it has heretofore not been recognized in the prior art whether the silicon-hydrogen mix can be re-grown into single crystalline silicon using solid phase epitaxy. Additionally, it has not been understood whether the hydrogen filled bubbles, hydrogen platelets, and hydrogenated vacancy clusters can be healed at low temperatures (e.g., under 600° C.).

One or more features disclosed herein describe healing of damage in the exfoliated semiconductor layer at temperatures that will not warp, degrade, or otherwise damage a glass substrate supporting the semiconductor layer. By way of example, the damaged, single crystalline silicon layer of a silicon-on-glass structure is implanted with silicon in a dose sufficient to amorphize the silicon material. The energy of the implantation is in a range sufficient to amorphize an upper, damaged portion of the single crystalline silicon, but not sufficient to amorphize the entire silicon layer. The pre-implanted substrates are then annealed at a temperature in a range between about 550° C. and 650° C. to transform the amorphous layer into a single crystalline layer. The lower, non-amorphized portion of the silicon layer serves as a seed for solid phase epitaxial re-growth. The resulting semiconductor layer therefore exhibits good structural and electrical properties.

In accordance with one or more embodiments disclosed herein, methods and apparatus of forming a semiconductor on glass structure, include: subjecting an implantation surface of a donor semiconductor wafer to an ion implantation process to create an exfoliation layer of the donor semiconductor wafer; bonding the implantation surface of the exfoliation layer to a glass substrate using electrolysis; separating the exfoliation layer from the donor semiconductor wafer, thereby exposing at least one cleaved surface; subjecting the at least one cleaved surface to an amorphization ion implantation process at a dose sufficient to amorphize at least some depth of the semiconductor material below the at least one cleaved surface; and re-growing the amorphized portion of the semiconductor material into a substantially single crystalline semiconductor layer using solid phase epitaxial re-growth.

Other aspects, features, advantages, etc. will become apparent to one skilled in the art when the description herein is taken in conjunction with the accompanying drawings.

### BRIEF DESCRIPTION OF THE DRAWINGS

For the purposes of illustrating the various features disclosed herein, there are shown in the drawings forms that are presently preferred, it being understood, however, that the invention is not limited to the precise arrangements and instrumentalities shown.

FIG. 1 is a block diagram illustrating the structure of an SOG device in accordance with one or more embodiments disclosed herein;

FIGS. 2-5 are block diagrams illustrating intermediate structures formed using a semiconductor-to-glass bonding process in accordance with one or more features disclosed;

FIG. 6 is a graph illustrating the characteristics of the semiconductor material of a silicon exfoliation layer of the intermediate structure of FIG. 5 before, during and after defect healing according to one or more features disclosed herein;

FIG. 7 is a further intermediate structure formed using an amorphization ion implantation process in accordance with one or more features disclosed herein;

FIGS. 8A-8D are graphs illustrating characteristics useful in determining amorphization ion implantation dose and energy to achieve amorphization ion implantations within certain depths; and

FIG. 9 is an X-ray diffraction spectra of the semiconductor exfoliation layer before, during and after defect healing according to one or more features disclosed herein.

### DETAILED DESCRIPTION

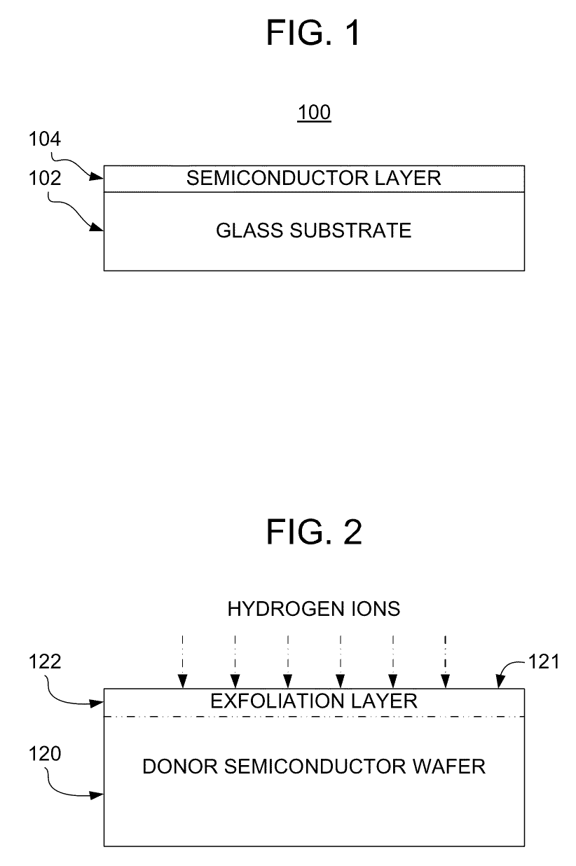

With reference to the drawings, wherein like numerals indicate like elements, there is shown in FIG. 1 an SOG structure 100 in accordance with one or more embodiments disclosed herein. The SOG structure 100 may include a glass substrate 102, and a semiconductor layer 104. The SOG structure 100 has suitable uses in connection with fabricating thin film transistors (TFTs), e.g., for display applications, including organic light-emitting diode (OLED) displays and liquid crystal displays (LCDs), integrated circuits, photovoltaic devices, etc.

The semiconductor material of the layer 104 may be in the form of a substantially single-crystal material. The term “substantially” is used in describing the layer 104 to take account of the fact that semiconductor materials normally contain at least some internal or surface defects either inherently or purposely added, such as lattice defects or a few grain boundaries. The term substantially also reflects the fact that certain dopants may distort or otherwise affect the crystal structure of the semiconductor material.

For the purposes of discussion, it is assumed that the semiconductor layer 104 is formed from silicon. It is understood, however, that the semiconductor material may be a silicon-based semiconductor or any other type of semiconductor, such as, the III-V, II-IV, II-IV-V, etc. classes of semiconductors. Examples of these materials include: silicon (Si), germanium-doped silicon (SiGe), silicon carbide (SiC), germanium (Ge), gallium arsenide (GaAs), GaP, and InP.

The glass substrate 102 may be formed from an oxide glass or an oxide glass-ceramic. Although not required, the embodiments described herein may include an oxide glass or glass-ceramic exhibiting a strain point of less than about 1,000 degrees C. As is conventional in the glass making art, the strain point is the temperature at which the glass or glass-ceramic has a viscosity of 10^{14.6} poise (10^{13.6} Pa.s). As between oxide glasses and oxide glass-ceramics, the glasses may have the advantage of being simpler to manufacture, thus making them more widely available and less expensive.

By way of example, the glass substrate 102 may be formed from glass substrates containing alkaline-earth ions, such as, substrates made of CORNING INCORPORATED GLASS COMPOSITION NO. 1737 or CORNING INCORPORATED GLASS COMPOSITION NO. EAGLE 2000™. These glass materials have particular use in, for example, the production of liquid crystal displays.

The glass substrate may have a thickness in the range of about 0.1 mm to about 10 mm, such as in the range of about 0.5 mm to about 3 mm. For some SOI structures, insulating layers having a thickness greater than or equal to about 1 micron are desirable, e.g., to avoid parasitic capacitive effects which arise when standard SOI structures having a silicon/silicon dioxide/silicon configuration are operated at high frequencies. In the past, such thicknesses have been difficult to achieve. In accordance with the present invention, an SOI structure having an insulating layer thicker than about 1 micron is readily achieved by simply using a glass substrate 102 having a thickness that is greater than or equal to about 1 micron. A lower limit on the thickness of the glass substrate 102 may be about 1 micron.

In general, the glass substrate 102 should be thick enough to support the semiconductor layer 104 through the bonding process steps, as well as subsequent processing performed on the SiOG structure 100. Although there is no theoretical upper limit on the thickness of the glass substrate 102, a thickness beyond that needed for the support function or that desired for the ultimate SOG structure 100 might not be advantageous since the greater the thickness of the glass substrate 102, the more difficult it will be to accomplish at least some of the process steps in forming the SOG structure 100.

Reference is now made to FIGS. 2-5, which illustrate intermediate structures that may be formed in carrying out the process of manufacturing the SOG structure 100 of FIG. 1 in accordance with one or more aspects of the present invention.

Turning first to FIG. 2, an implantation surface 121 of a donor semiconductor wafer 120 is prepared, such as by polishing, cleaning, etc. to produce a relatively flat and uniform implantation surface 121 suitable for bonding to the glass or glass-ceramic substrate 102. For the purposes of discussion, the semiconductor wafer 120 may be a substantially single crystal Si wafer, although as discussed above any other suitable semiconductor conductor material may be employed.

An exfoliation layer 122 is created by subjecting the implantation surface 121 to one or more ion implantation processes to create a weakened region below the implantation surface 121 of the donor semiconductor wafer 120. Although the embodiments of the present invention are not limited to any particular method of forming the exfoliation layer 122, one suitable method dictates that the implantation surface 121 of the donor semiconductor wafer 120 may be subject to a hydrogen ion implantation process to at least initiate the creation of the exfoliation layer 122 in the donor semiconductor wafer 120. The implantation energy may be adjusted using conventional techniques to achieve a general thickness of the exfoliation layer 122, such as between about 300-500 nm, although any reasonable thickness is within the scope of the invention. By way of example, hydrogen ion implantation may be employed, although other ions or multiples thereof may be employed, such as boron+hydrogen, helium+hydrogen, or other ions known in the literature for exfoliation. Again, any other known or hereinafter developed technique suitable for forming the exfoliation layer 122 may be employed without departing from the spirit and scope of the present invention.

Regardless of the nature of the implanted ion specie, the effect of implantation on the exfoliation layer 122 is the displacement of atoms in the crystal lattice from their regular locations. When the atom in the lattice is hit by an ion, the atom is forced out of position and a primary defect, a vacancy and an interstitial atom, is created, which is called a Frenkel's pair. If the implantation is performed near room temperature, the components of the primary defect move and create many types of secondary defects, such as vacancy clusters, etc. The vacancy clusters may be annealed at temperatures exceeding 900° C.; however, as discussed above, to completely heal implant-induced damaged by annealing, the exfoliation layer 122 would have to be heated to a temperature approaching the melting temperature of the semiconductor material, which would warp or even melt the glass substrate 102 (which is added later in the manufacturing process). If annealing was carried out at a lower temperature, such as 600° C., the exfoliation layer 122 would still contain defects, such as the aforementioned vacancy clusters and other impurity-vacancy clusters. Most of these types of defects are electrically active, and serve as traps for major carriers in the semiconductor lattice. Therefore, the concentration of free carriers in the exfoliation layer 122 is lower when post-implantation defects are present. The electrical resistivity of defect laden semiconductor material is also worsened compared to defect-free semiconductor material. A process for healing the implantation-induced defects will be discussed later in this description.

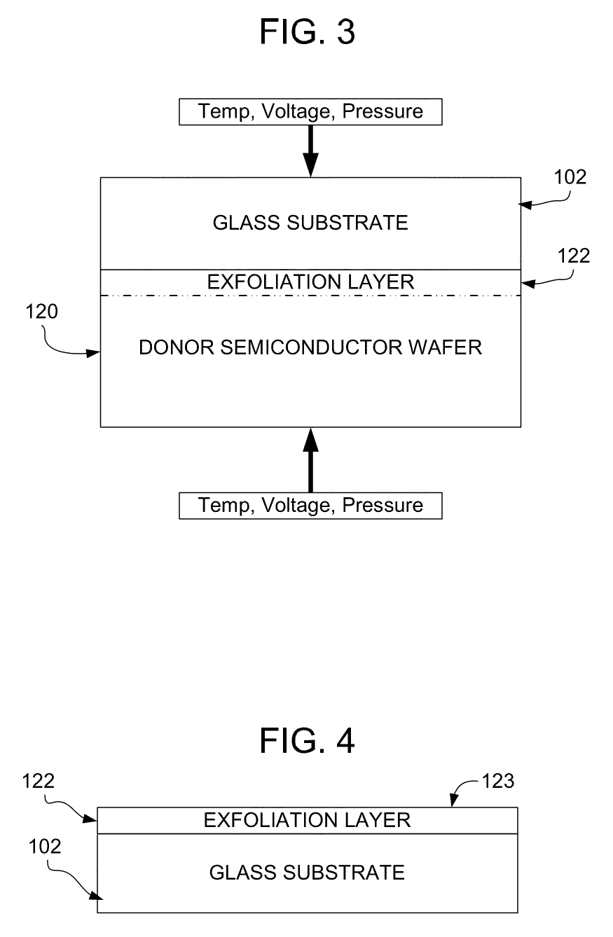

With reference to FIG. 3, the glass substrate 102 may be bonded to the exfoliation layer 122 using an electrolysis process. A suitable electrolysis bonding process is described in U.S. Pat. No. 7,176,528, the entire disclosure of which is hereby incorporated by reference. Portions of this process are discussed below. In the bonding process, appropriate surface cleaning of the glass substrate 102 (and the exfoliation layer 122 if not done already) may be carried out. Thereafter, the intermediate structures are brought into direct or indirect contact to achieve the arrangement schematically illustrated in FIG. 3. Prior to or after the contact, the structure(s) comprising the donor semiconductor wafer 120, the exfoliation layer 122, and the glass substrate 102 are heated under a differential temperature gradient. The glass substrate 102 may be heated to a higher temperature than the donor semiconductor wafer 120 and exfoliation layer 122. By way of example, the temperature difference between the glass substrate 102 and the donor semiconductor wafer 120 (and the exfoliation later 122) is at least 1° C., although the difference may be as high as about 100 to about 150° C. This temperature differential is desirable for a glass having a coefficient of thermal expansion (CTE) matched to that of the donor semiconductor wafer 120 (such as matched to the CTE of silicon) since it facilitates later separation of the exfoliation layer 122 from the semiconductor wafer 120 due to thermal stresses.

Once the temperature differential between the glass substrate 102 and the donor semiconductor wafer 120 is stabilized, mechanical pressure is applied to the intermediate assembly. The pressure range may be between about 1 to about 50 psi. Application of higher pressures, e.g., pressures above 100 psi, might cause breakage of the glass substrate 102.

The glass substrate 102 and the donor semiconductor wafer 120 may be taken to a temperature within about ±150° C. of the strain point of the glass substrate 102.

Next, a voltage is applied across the intermediate assembly, for example with the donor semiconductor wafer 120 at the positive electrode and the glass substrate 102 the negative electrode. The application of the voltage potential causes alkali or alkaline earth ions in the glass substrate 102 to move away from the semiconductor/glass interface further into the glass substrate 102. This accomplishes two functions: (i) an alkali or alkaline earth ion free interface is created; and (ii) the glass substrate 102 becomes very reactive and bonds strongly to the exfoliation layer 122 of the donor semiconductor wafer 120 with the application of heat at relatively low temperatures.

With reference to FIG. 4, after the intermediate assembly is held under the above conditions for some time (e.g., approximately 1 hour or less), the voltage is removed and the intermediate assembly is allowed to cool to room temperature. At some point during heating, during a dwell, during cooling, and/or after cooling, the donor semiconductor wafer 120 and the glass substrate 102 are separated, which may include some peeling if they have not already become completely free, to obtain a glass substrate 102 with the relatively thin exfoliation layer 122 formed of the semiconductor material of the donor semiconductor layer 120 bonded thereto. The separation may be accomplished via fracture of the exfoliation layer 122 due to thermal stresses. Alternatively or in addition, mechanical stresses such as water jet cutting or chemical etching may be used to facilitate the separation.

After separation, the resulting structure may include the glass substrate 102 and the exfoliation layer 122 of semiconductor material bonded thereto. The cleaved surface 123 of the SOI structure, just after exfoliation, may exhibit excessive surface roughness, excessive silicon layer thickness, and implantation damage of the silicon layer (e.g., due to the formation of an amorphized silicon layer). Depending on the implantation energy and implantation time, the thickness of the exfoliation layer 122 may be on the order of about 300-500 nm, although other thicknesses are within the scope of the invention.

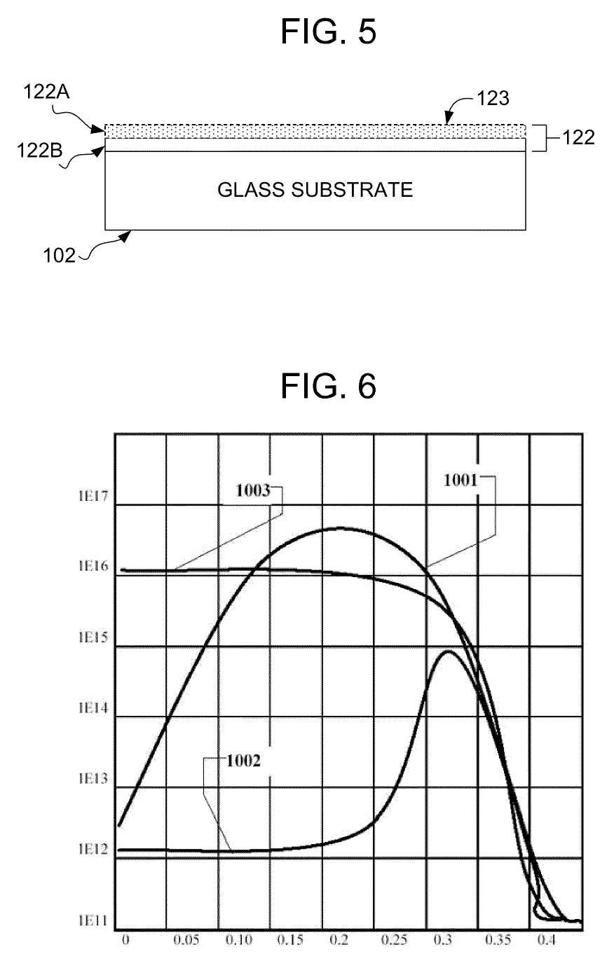

As best seen in FIG. 5, the exfoliation layer 122 of the intermediate structure includes two basic layers 122A, 122B. The first layer 122A, closest to the cleaved surface 123, includes implantation-induce defects and damage resulting from the ion implantation process described with respect to FIG. 2. The second layer 122B is substantially free from any implantation-induced defects. The highest concentration of defects within the first layer 122A is expected nearest to the cleaved surface 123.

FIG. 6 is a graph illustrating the characteristics of the semiconductor material of the exfoliation layer 122 of the intermediate structure of FIG. 5 before ion implantation (i.e., the state of the donor semiconductor wafer 120), after ion implantation (i.e., the state of the first layer 122A), and after defect healing according to one or more aspects of the present invention. In particular, the Y-axis of FIG. 6 is carrier concentration (a measure of material resistivity behavior) as a function of the concentration of current carriers in the semiconductor material. The concentration of the carriers is inversely proportional to the resistivity of the semiconductor material, such as silicon. The X-axis is the depth of the semiconductor material of the exfoliation layer 122. The origin of the X-axis is at the surface of the exfoliation layer 122, and the thickness of the semiconductor material thereof is about 0.39 microns. Thus, to the far right along the X-axis, beyond 0.39 microns, is a plot of the resistivity of glass (although the spreading resistivity technique used to produce these plots does not yield an accurate measurement for glass materials).

The curve labeled 1001 in FIG. 6 shows the distribution of carrier concentration in the donor semiconductor wafer 120 (formed of silicon) before ion implantation. There is an undesirable drop in carrier concentration toward the surface of the silicon semiconductor layer of the donor semiconductor wafer 120. The carrier concentration drop is due to high levels of defects in this region. The curve labeled 1002 shows a typical carrier concentration profile after ion implantation into the silicon forming the exfoliation layer 122. The 1002 curve shows very low carrier concentration in the first layer 122A of the exfoliation layer 122. This characteristic is evident because the amorphization due to ion implantation into the exfoliation layer 122 creates a semi-insulating region therein.

The curve labeled 1003 shows a typical carrier concentration profile of the exfoliation layer 122 after a healing process is carried out in accordance with one or more aspects of the present invention using SPE. This process will be discussed in detail below—then a further discussion of the 1003 curve will be provided.

The carrier concentration curves 1001 and 1002 of FIG. 6 provide information as to the depth of the exfoliation layer 122 containing defects that require healing. As defects exist to about 0.15 microns on the 1001 curve, a healing treatment to that depth or beyond would be desirable. The treatment, however, should not extend all the way through the exfoliation layer 122 as will be discussed in more detail below.

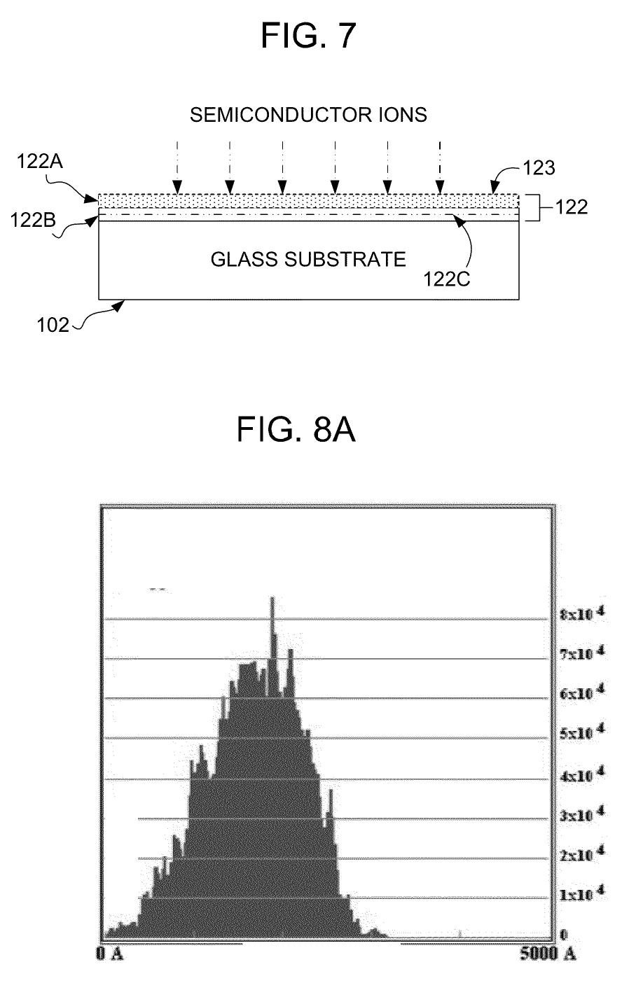

With reference to FIG. 7, the healing process includes subjecting the cleaved surface 123 of the exfoliation layer 122 to an amorphization ion implantation process at a dose sufficient to amorphize at least some depth of the semiconductor material below the cleaved surface 123. Thereafter, the amorphized portion of the semiconductor material is re-grown into a substantially single crystalline semiconductor layer using solid phase epitaxial re-growth. The specific type or species of ion that is desirable for this implantation process is that which would amorphize at least a portion of the exfoliation layer 122, but which would not adversely change the electrical properties or stability of the exfoliation layer 122. In other words, the implanted amorphization ions should amorphize the semiconductor material of the exfoliation layer 122, but permit later re-growth of the exfoliation layer back into a substantially single crystalline semiconductor layer using solid phase epitaxial re-growth—and the resultant substantially single crystalline semiconductor material should not exhibit degraded electrical or stability characteristics as compared with those of the original semiconductor material of the exfoliation layer 122. For example, when the exfoliation layer 123 is of a silicon semiconductor material, then suitable amorphization ions would be silicon ions. More generally, the amorphization ions may be of the same species as the specific semiconductor material of the exfoliation layer 122. If an ion that is not of the same species as the specific semiconductor material of the exfoliation layer 122 is known or hereinafter developed to satisfy the above constraints (e.g., causing amorphization without adverse impact on the electrical or stability properties of the exfoliation layer, and permitting SPE re-growth), then such ions may also be suitable candidates for the amorphization ion implantation process.

An energy level and/or a dose of the amorphization ion implantation may be in respective ranges sufficient to amorphize the upper portion, the first layer 122A, of the semiconductor material of the exfoliation layer 122 closest to the cleaved surface 123, but not sufficient to amorphize the lower portion, the second layer 122B, thereof.

The implantation dose should be chosen to ensure amorphization of the desired depth. If the implantation dose is to low, amorphization does not result, as there are not enough displacements made in the lattice. For the case of silicon-into-silicon amorphization ion implantation, the critical dose for amorphization is about 5E14 cm-3. After reaching the critical amorphization dose, further implantation will result in a widening of the amorphized region. Exceeding the critical amorphization dose by less than an order of magnitude should not widen the amorphized region significantly, which should reduce the risk of amorphizing the entire exfoliation layer 122.

In accordance with one embodiment, the amorphization ion implantation process includes at least two amorphization ion implantation steps. (It is understood that, although a two or more step amorphization ion implantation process may be preferred, a single may also be performed without departing from the scope of the invention.) In a two step process, a first of the amorphization ion implantation steps is carried out at a first energy level, such as at an energy of more than about 100 keV. A second of the amorphization ion implantation steps is carried out at a second energy level, such as an energy of less than about 100 keV. The second amorphization ion implantation step amorphizes the upper portion, layer 122A, of the exfoliation layer 122 closest to the cleaved surface 123.

By way of example, the energy of the first amorphization ion implantation step may be about 120 keV at a dose of greater than about 5E14 cm-3, and the energy of the second amorphization ion implantation step may be about 20 keV at a dose of greater than about 5E14 cm-3. With above considerations, the dose of the first and second amorphization ion implantation step may be about 2E15 cm-3 (exceeding the critical amorphization dose by about four times).

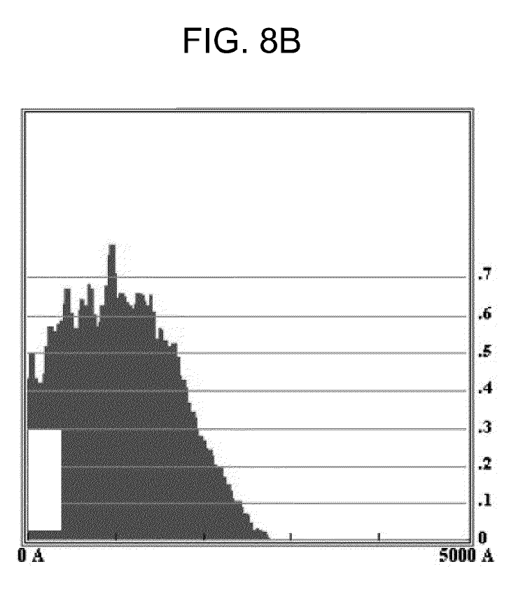

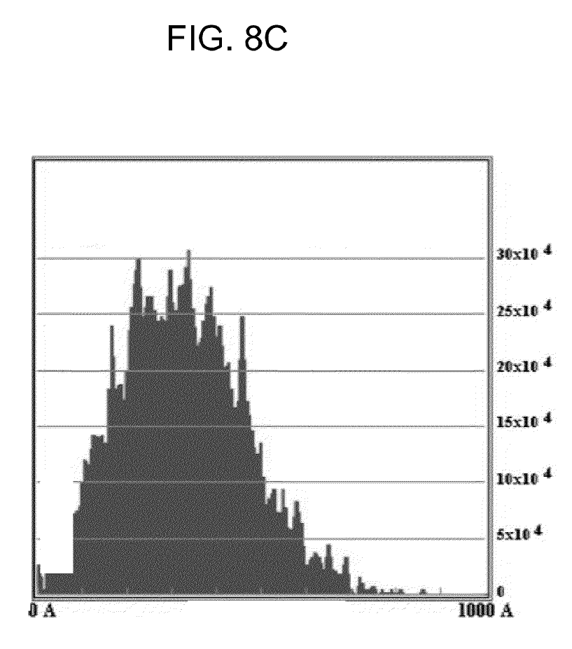

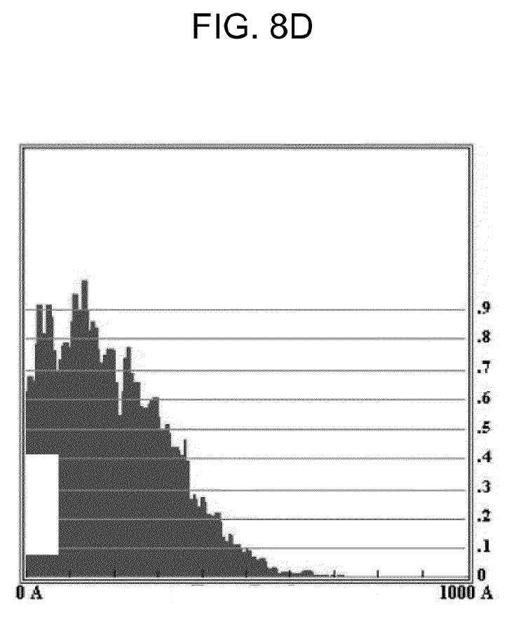

Details as to the technical rational for using the above-discussed energy levels and multiple implantation steps will now be discussed with reference to FIGS. 8A-8D. The plots of FIGS. 8A-8D are simulation results illustrating implantation characteristics as to a silicon exfoliation layer 122. The plot of FIG. 8A shows that silicon ions of an energy of 120 keV will penetrate into the exfoliation layer 122 to a depth of almost 0.3 microns, with a maximum penetration at 0.166 microns. As substantially no ions go deeper than about 0.3 microns, such an energy level ensures that at least about the lower 0.1 microns of the second layer 122B of the overall 0.39 micron depth will remain single crystalline semiconductor material. This single crystalline semiconductor material of the second layer 122B will thus be available as a seed for the epitaxial re-growth via SPE.

The energy level of the amorphization ion implantation must be sufficient to penetrate farther than the minimum required thickness of about 0.15 microns (discussed above with respect to FIG. 6, plot 1001)—in order to amorphize the semiconductor material of the first layer 122A. The plot of FIG. 8B shows the vacancy distribution resulting from the 120 keV silicon ion implant into the exfoliation layer 122. This plot gives a better estimation of the amorphization depth as compared to the ion projection range plot of FIG. 8A. The plot of FIG. 8B is shifted toward the surface of the exfoliation layer 122 as compared to the plot of FIG. 8A. It may be estimated therefore, that the 120 keV silicon ion implant will reach a depth of about 0.16 micron with attendant amorphization.

The plots of FIGS. 8A and 8B show that the portion of the first layer 122A near the cleaved surface 123 will receive significantly less displacement compared to the depth of 0.15 microns. To ensure that such higher portions of the exfoliation layer 122 (especially near the cleaved surface 123) will also be amorphized, the second amorphization ion implantation step (at lower energy) is believed useful. The plots of FIGS. 8C and 8D show the projection range and displacement for a lower, 20 keV amorphization ion implantation into the exfoliation layer 122. The plots of FIGS. 8C and 8D are similar to those of FIGS. 8A and 8B (at the higher energy), but the resultant depth is scaled down by several times. Thus, the lower energy, amorphization ion implantation step may be used to ensure that the portions of the exfoliation layer 122 near the cleaved surface 123 will be amorphized.

Again, once the cleaved surface 123 of the exfoliation layer 122 has been subject to the amorphization ion implantation process, the amorphized portion of the exfoliation layer 122 is re-grown into a substantially single crystalline semiconductor layer using solid phase epitaxial (SPE) re-growth. The non-amorphized portion of the second layer 122B is used as a seed layer for the SPE re-growth process. In particular, the amorphized semiconductor material of the exfoliation layer 122 is subject to an annealing process in order to re-grow the amorphized portion of the semiconductor material into a substantially single crystalline semiconductor layer. The annealing process may be performed at a temperature in a range between about 550° C. to about 650° C. for a period of time. The period of time may be about 12 hours.

Alternative embodiments are directed to the specific results of separating the exfoliation layer 122 from the donor semiconductor wafer 120. As discussed above, the exfoliation process may produce a first cleaved surface of the donor semiconductor wafer 120 and the (second) cleaved surface 123 of the exfoliation layer 122. As previously discussed, the process of amorphization ion implantation and SPE re-growth may be applied to the second cleaved surface 123 of the exfoliation layer 122. Additionally or alternatively, the process of amorphization ion implantation and SPE re-growth may be applied as well to the first cleaved surface of the donor semiconductor wafer 120 (using one or more of the techniques described above).

Compared to prior art techniques of addressing the implantation damage problem, the embodiments of the present invention are less expensive to implement. For example, the prior art polishing technique requires at least one hour per square foot of polishing time, resulting in only a 50 nm or less material removal. In contrast, the SPE techniques of one or more embodiments of the present invention require very low dose amorphization ion implantation (on the order of about 1E15 cm-2), which takes only a few seconds via standard ion implanters. Therefore, at the amorphization ion implantation stage, it is relatively straight forward to obtain a manufacturing throughput exceeding about 100 substrates per hour.

While the SPE technique of the present invention may require a furnace annealing step of about 12 hours long, the annealing may be carried out using a batch process, such that hundreds of substrates may be annealed simultaneously. Therefore, the annealing manufacturing throughput may be estimated at about ten substrates per hour for a single furnace, e.g., about an order of magnitude higher as compared to the prior art polishing technique.

Compared to the prior art polishing technique, the one or more methods of the present invention result in higher quality final products. Indeed, the polishing process results in degradation of thickness uniformity of the exfoliation layer 122, while the SPE processes do not affect thickness uniformity. This advantage is more pronounced for very thin exfoliation layers of about 100 nanometers and less.

Compared to the prior art excimer laser annealing (ELA) technique, the one or more methods of the present invention also result in significantly higher quality final products. The exfoliation layer 122 (post SPE re-growth) according to the invention contains between one to several orders of magnitude lower electrically active defects as compared to ELA, and does not create detrimental periodic thickness variation patterns on the surface of the exfoliation layer 122. In addition, the SPE healing technique of the present invention may also be less expensive than the ELA technique. ELA equipment is about the same cost as ion implantation equipment, but throughput using the ELA equipment is much lower as compared to use of the ion implantation equipment.

An experiment was conducted to demonstrate the applicability of the aforementioned healing process on SOG structures. Silicon-on-glass structures were obtained using the bonding technique described in U.S. Pat. No. 7,399,681, the entire disclosure of which is hereby incorporated by reference. Silicon wafers having p-type conductivity, boron doping and a resistivity of about one Ohm×cm were used as donor semiconductor wafers 120. The carrier concentration of silicon is about 10E16 cm-3 as converted using a standard SEMI MF723. Glass substrates formed of CORNING INCORPORATED GLASS COMPOSITION NO. EAGLE 2000™ were used as the substrates 102. Ionized molecular hydrogen species H2+ was used to create the exfoliation layers 122 via ion implantation. An implantation energy of 80 keV, and a dose of 4E16 cm-3 was used in the implantation process. The resulting exfoliation layers 122 had thicknesses of about 400 nm.

After separation of the exfoliation layer 122 (and substrate 102) from the donor semiconductor wafer 120, the newly formed silicon-on-glass substrate was annealed at 600° C. (about 50° C. higher than the anodic bonding step) in a furnace for 12 hours. This temperature is about as high a temperature as the Eagle 2000™ glass can withstand.

The silicon-on-glass structures had a typical yellow color and translucent appearance before amorphization ion implantation. This was an indication that the exfoliation layers 122 were essentially single crystalline.

The exfoliated silicon-on-glass structure was subject to an amorphization ion implantation step which included two silicon ion implantation steps; (1) in the first step silicon ions were implanted at an energy of about 120 keV at a dose of greater than about 1E15 cm-3; (2) in the second step silicon ions were implanted at an energy of about 20 keV at a dose of 1E15 cm-3. After amorphization ion implantation, the appearance of the silicon-on-glass structures changed completely, the exfoliation layers 122 were black in color. This was an indication that at least part of exfoliation layers 122 had been amorphized.

The amorphization ion implanted silicon-on-glass structures were further annealed at 600° C. for 12 hours. The optical appearance of the silicon-on-glass structures changed again, from black back to translucent yellow. This was an indication that the previously amorphous exfoliation layer 122 again became single crystalline; i.e., the surface of the exfoliation had been healed.

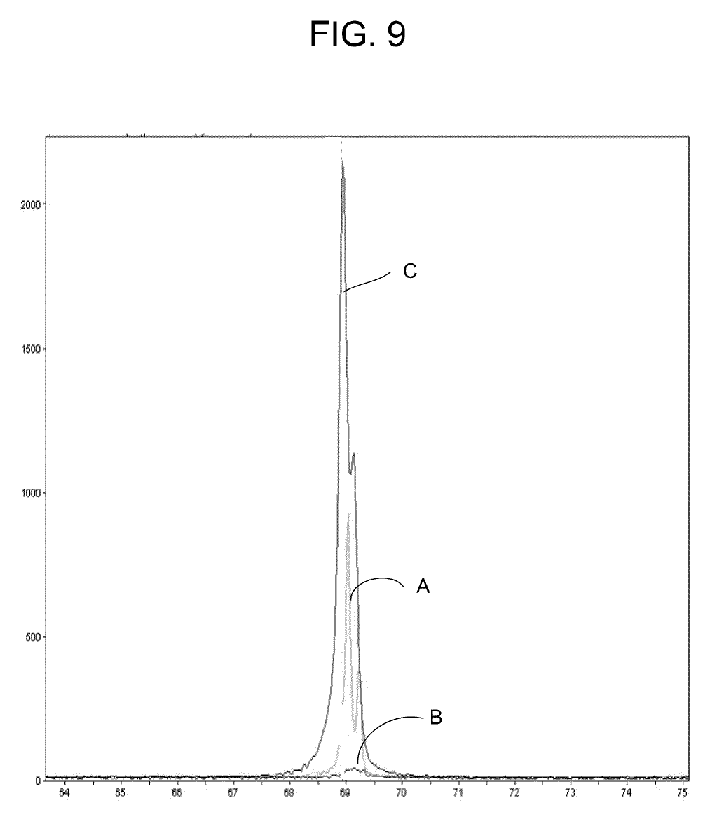

With reference to FIG. 9, in addition to the optical observation, x-ray diffraction curves were obtained at each of three stages: (a) plot A, at a first stage after exfoliation and the initial 600° C. anneal process; (b) plot B, at a second stage after amorphization ion implantation, and (c) plot C, a third stage after the second 600° C. anneal. The x-ray diffraction spectra give an overall indication of the crystallinity of the exfoliation layer 122 during each stage. The heights of the respective peaks in the spectra provide an indication of the crystallinity. The peak for plot A (after exfoliation and the initial 600° C. anneal process) is relatively high indicating relatively good crystallinity. The peak for plot B (after amorphization ion implantation) has almost no peak, which indicates that the exfoliation layer 122 has virtually no crystallinity. The peak for plot C (after the second 600° C. anneal) has the highest magnitude, which means that the crystallinity has been restored, and is even better than the first stage.

Electrical properties of the SOG structures after exfoliation and the initial 600° C. anneal process, after amorphization ion implantation, and after the second 600° C. anneal were also measured. A spreading resistance profiling technique was used to characterize these electrical properties. The results were discussed above with respect to FIG. 6. The curve labeled 1001 in FIG. 6 shows the distribution of carrier concentration in the donor semiconductor wafer 120 (formed of silicon) before ion implantation. The curve labeled 1002 shows a typical carrier concentration profile after ion implantation into the silicon forming the exfoliation layer 122. The 1002 curve shows very low carrier concentration in the first layer 122A of the exfoliation layer 122. This characteristic is evident because the amorphization due to ion implantation into the exfoliation layer 122 creates a semi-insulating region therein. The curve labeled 1003 shows a typical carrier concentration profile of the exfoliation layer 122 after a healing process is carried out in accordance with one or more aspects of the present invention using SPE; i.e., amorphization ion implantation followed by annealing. After the SPE healing process, the carrier concentration level in the entire semiconductor material of the exfoliation layer 122 is restored. There is no undesirable drop in carrier concentration near the surface 123 of the exfoliation layer 122. The 1003 curve indicates that the silicon material of the exfoliation layer 122 after the SPE process has much lower concentrations of defects as compared to the exfoliation layer 122 (particularly layer 122A) just after bonding and separation from the donor semiconductor wafer 120.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A method of forming a semiconductor on glass structure, comprising:
subjecting an implantation surface of a donor semiconductor wafer to an ion implantation process to create an exfoliation layer of the donor semiconductor wafer;
bonding the implantation surface of the exfoliation layer to a glass substrate using electrolysis;
separating the exfoliation layer from the donor semiconductor wafer, thereby exposing at least one cleaved surface;
subjecting the at least one cleaved surface to an amorphization ion implantation process at a dose sufficient to amorphize at least some depth of the semiconductor material below the at least one cleaved surface; and
re-growing the amorphized portion of the semiconductor material into a substantially single crystalline semiconductor layer using solid phase epitaxial re-growth.

2. The method of claim 1, wherein an energy of the amorphization ion implantation is in a range sufficient to amorphize an upper portion of the semiconductor material closest to the at least one cleaved surface, but not sufficient to amorphize a lower portion of the semiconductor material farther from the at least one cleaved surface.

3. The method of claim 1, wherein the amorphization ion implantation process includes at least two amorphization ion implantation steps, a first of the amorphization ion implantation steps at an energy of more than about 100 keV, and a second of the amorphization ion implantation steps at an energy of less than about 100 keV, the second amorphization ion implantation step amorphizing the upper portion of the semiconductor material closest to the at least one cleaved surface.

4. The method of claim 3, wherein the energy of the first amorphization ion implantation step is about 120 keV at a dose of greater than about 5E14 cm-3, and the energy of the second amorphization ion implantation step is about 20 keV at a dose of greater than about 5E14 cm-3.

5. The method of claim 4, wherein the dose of the first and second amorphization ion implantation step is about 2E15 cm-3.

6. The method of claim 1, further comprising subjecting the amorphized semiconductor material to an annealing process in order to re-grow the amorphized portion of the semiconductor material into a substantially single crystalline semiconductor layer.

7. The method of claim 6, wherein the annealing process is performed at a temperature in a range between about 550° C. to about 650° C. for a period of time.

8. The method of claim 7, wherein the period of time is about 12 hours.

9. The method of claim 1, wherein the at least one cleaved surface includes a first cleaved surface of the donor semiconductor wafer and a second cleaved surface of the exfoliation layer.

10. The method of claim 9, wherein the steps of subjecting the at least one cleaved surface to the amorphization ion implantation process, and subjecting the amorphized portion of the semiconductor material to the re-growth process is applied to at least one of:
the second cleaved surface of the exfoliation layer; and
the first cleaved surface of the donor semiconductor wafer.

11. The method of claim 1, wherein the step of bonding includes:
heating at least one of the glass substrate and the donor semiconductor wafer;
bringing the glass substrate into direct or indirect contact with the donor semiconductor wafer through the exfoliation layer; and
applying a voltage potential across the glass substrate and the donor semiconductor wafer to induce the bond.

12. The method of claim 1, wherein the donor semiconductor wafer is taken from the group consisting of: silicon (Si), germanium-doped silicon (SiGe), silicon carbide (SiC), germanium (Ge), gallium arsenide (GaAs), GaP, and InP.

13. A method of forming a semiconductor on glass structure, comprising:
bonding a surface of a donor semiconductor structure to a glass substrate using electrolysis;
separating a layer, bonded to the glass substrate, from the donor semiconductor structure by exfoliation, thereby exposing at least one cleaved surface;
subjecting the at least one cleaved surface to an amorphization ion implantation process at a dose sufficient to amorphize at least some depth of the semiconductor material below the at least one cleaved surface; and
re-growing the amorphized portion of the semiconductor material into a substantially single crystalline semiconductor layer using solid phase epitaxial re-growth.
